(19) United States
(12) Patent Application Publication
(10) Pub. No.: US 2023/0403908 A1
(43) Pub. Date: Dec. 14, 2023

(54) OLED DISPLAY SUBSTRATE, METHOD FOR MANUFACTURING THE SAME, AND DISPLAY DEVICE

(71) Applicant: BOE Technology Group Co., Ltd., Beijing (CN)

(72) Inventors: Hao GAO, Beijing (CN); Xin LI, Beijing (CN); Xing FAN, Beijing (CN); Cheng HAN, Beijing (CN); Yansong LI, Beijing (CN)

(21) Appl. No.: 17/915,755

(22) PCT Filed: Nov. 11, 2021
(86) PCT No.: PCT/CN2021/130054

§ 371 Date: Sep. 29, 2022

(30) Foreign Application Priority Data
Mar. 2, 2021 (CN) 202110231564.6

(51) Int. Cl. H10K 59/80; H10K 59/12

(52) U.S. Cl. CPC H10K 59/873; H10K 59/879; H10K 59/1201; H10K 2102/351

(57) ABSTRACT

This invention provides an OLED display substrate, a method for manufacturing the same, and a display device, which belongs to the technical field of displays. The OLED display substrate includes: a drive substrate, the drive substrate being provided with a light-emitting unit; and an encapsulation structure covering the light-emitting unit. The encapsulation structure comprises a first inorganic structure, an organic layer and a second inorganic structure arranged in sequence along a direction away from the drive substrate. A refractive index of the first inorganic structure is higher than a refractive index of the organic layer, the first inorganic structure comprises at least one inorganic layer, and a thickness of one inorganic layer of the at least one inorganic layer is not larger than 500 nm. With the technical solution of this invention, the display effect of the OLED display substrate can be improved.

This application claims a priority to Chinese Patent Application No. 202110231564.6 filed in China on Mar. 2, 2021, the entire contents of which are hereby incorporated by reference.

### TECHNICAL FIELD

The present disclosure relates to the technical field of displays, and more particularly, to an OLED display substrate, a method for manufacturing the same, and a display device.

### BACKGROUND

OLED (Organic Light-Emitting Diode) display devices have been listed as the most promising next-generation display technology due to their advantages such as thinness, light weight, wide viewing angle, active light emission, continuously adjustable emission color, low cost, fast response, low power consumption, low driving voltage, wide operating temperature range, simple production process, high light emission efficiency and flexible display.

### SUMMARY

Embodiments of the present disclosure provide the following technical solutions.

In an aspect, an OLED display substrate is provided, which includes: a drive substrate, the drive substrate being provided with a light-emitting unit; and an encapsulation structure covering the light-emitting unit. The encapsulation structure includes a first inorganic structure, an organic layer and a second inorganic structure arranged in sequence along a direction away from the drive substrate. A refractive index of the first inorganic structure is higher than a refractive index of the organic layer, the first inorganic structure includes at least one inorganic layer, and a thickness of one inorganic layer of the at least one inorganic layer is not larger than 500 nm.

In some embodiments, along the direction away from the drive substrate, the first inorganic structure includes a first inorganic layer and a second inorganic layer that are laminated, a refractive index of the first inorganic layer is lower than a refractive index of the second inorganic layer, and a thickness of the first inorganic layer is not larger than 500 nm.

In some embodiments, the thickness of the first inorganic layer is not larger than 100 nm, and a thickness of the second inorganic layer is not larger than 500 nm.

In some embodiments, a difference between the refractive index of the second inorganic layer and the refractive index of the organic layer is smaller than a preset threshold.

In some embodiments, the preset threshold is 0.15.

In some embodiments, a thickness of the organic layer is larger than 6000 nm.

In some embodiments, a thickness of the second organic layer is 10 nm to 50000 nm.

In some embodiments, a thickness of the second organic layer is larger than 1500 nm.

In some embodiments, the first inorganic structure includes only one first inorganic layer, and a thickness of the first inorganic layer is smaller than 500 nm.

An embodiment of the present disclosure further provides a display device, including the OLED display substrate described above.

An embodiment of the present disclosure further provides a method for manufacturing an OLED display substrate, which includes: providing a drive substrate; forming a light-emitting unit on the drive substrate; and forming an encapsulation structure covering the light-emitting unit. The forming the encapsulation structure includes: forming a first inorganic structure, an organic layer and a second inorganic structure in sequence, where a refractive index of the first inorganic structure is higher than a refractive index of the organic layer, the first inorganic structure includes at least one inorganic layer, and a thickness of one inorganic layer of the at least one inorganic layer is not larger than 500 nm.

In some embodiments, the forming the first inorganic structure includes: forming a first inorganic layer and a second inorganic layer that are laminated, a refractive index of the first inorganic layer is lower than a refractive index of the second inorganic layer, and a thickness of the first inorganic layer is not larger than 500 nm.

In some embodiments, the forming the first inorganic structure includes: forming a first inorganic layer, a thickness of the first inorganic layer being not larger than 500 nm.

In some embodiments, the forming the first inorganic layer includes: forming the first inorganic layer in an atomic layer deposition (ALD) manner.

### BRIEF DESCRIPTION OF THE DRAWINGS

FIG. 1 is a schematic diagram of an existing OLED display substrate;

FIG. 2 is a schematic diagram illustrating light propagation of an existing OLED display substrate;

FIG. 3 is a schematic diagram of an OLED display substrate according to an embodiment of the present disclosure;

FIGS. 4, 5 and 7 each is a schematic diagram illustrating light propagation of a display substrate according to embodiments of the present disclosure; and

FIG. 6 is a schematic diagram illustrating the improved display effect of an OLED display substrate according to an embodiment of the present disclosure.

### REFERENCE SIGNS

1 Drive substrate
2 Light-emitting unit
3 Polaroid
4 Protective layer
5 First inorganic layer
6 Organic layer
7 Third inorganic layer
8 Pixel definition layer
9 Second inorganic layer
10 Anode

### DETAILED DESCRIPTION

In order to make a technical problem to be solved by embodiments, a technical solution and an advantage of the present disclosure become more apparent, a detailed description will be given below with reference to the accompanying drawings and specific embodiments.

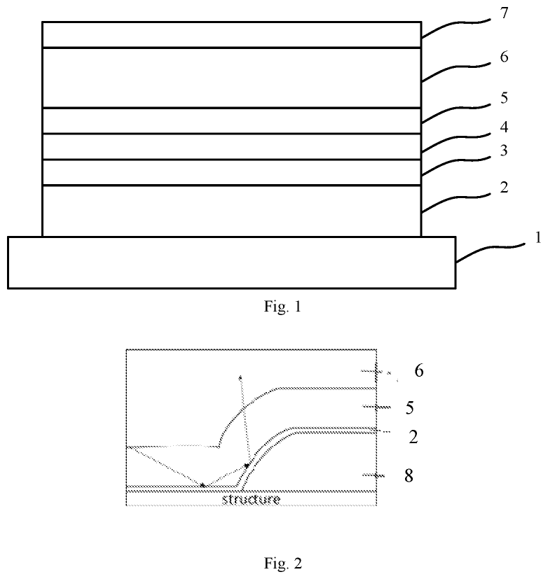

As shown in FIG. 1, an OLED display substrate includes a drive substrate 1, and a light-emitting unit 2, a polaroid 3, a protective layer 4 and an encapsulation structure located on the drive substrate 1. The drive substrate 1 includes a base substrate and a drive circuit on the base substrate, where the drive circuit includes a thin film transistor array and signal lines, etc. The flexible OLED display substrate is generally encapsulated with a thin film, and the encapsulation structure thereof is an encapsulation structure in which multiple layers of inorganic thin films are laminated. The inorganic thin film is usually dense, and the bending property of the inorganic thin film is poor, because there exists a thin film stress in the inorganic thin film during the deposition process, which easily causes cracking and peeling. Furthermore, in order to prevent water and oxygen from penetrating into the interior of the OLED display substrate, it is required that the inorganic thin film has a certain thickness to block water and oxygen, and the increase of the thickness of the inorganic thin film further aggravates the possibility of cracking and peeling, especially for an OLED flexible display substrate. When the OLED flexible display substrate is bent or folded, the problem of film cracking or peeling easily occurs at the inorganic film, thus leading to large-area failure of devices in the flexible OLED display substrate. Therefore, in order to reduce the stress, the encapsulation structure adopts a structure in which multiple layers of inorganic films and organic films are alternately deposited. As shown in FIG. 1, the encapsulation structure includes a first inorganic layer 5, an organic layer 6 and a third inorganic layer 7. The thickness of the first inorganic layer 5 may be about 1 um, the thickness of the organic layer 6 may be about 10 um, and the thickness of the third inorganic layer 7 may be about 0.8 um.

Each of refractive indexes of the first inorganic layer 5 and the third inorganic layer 7 is higher than the refractive index of the organic layer 6, and the difference between the refractive indexes is generally up to 0.4 or more. The difference of the refractive indexes at the interface between the first inorganic layer 5 and the organic layer 6 is relatively large, which results in that after the light emitted by the light-emitting unit enters the first inorganic layer 5, the first inorganic layer 5 forms an optical fiber-like structure in a planar structure, and as shown by arrows in FIG. 2, part of the light is trapped in the first inorganic layer 5 to form the waveguide light for transverse propagation. In a region of a pixel definition layer 8, since the first inorganic layer 5 has a certain thickness (about 1 μm), the parallelism of the first inorganic layer 5 becomes worse in this region, and part of the waveguide light is no longer totally reflected and does not propagate in the first inorganic layer 5, but is reflected by a slope of the first inorganic layer 5 at a position where the pixel definition layer 8 is located, and exits the first inorganic layer 5 and mixes with normal emergent light. The light intensity of a large viewing angle of the OLED display substrate is relatively low, and color deviation is relatively serious, due to the mixing with the waveguide light.

Embodiments of the present disclosure provide an OLED display substrate, a method for manufacturing the same, and a display device, which can improve the display effect of the OLED display substrate.

An embodiment of the present disclosure provides an OLED display substrate, which includes: a drive substrate, the drive substrate being provided with a light-emitting unit; and an encapsulation structure covering the light-emitting unit. The encapsulation structure includes a first inorganic structure, an organic layer and a second inorganic structure arranged in sequence along a direction away from the drive substrate. The refractive index of the first inorganic structure is higher than a refractive index of the organic layer, the first inorganic structure includes at least one inorganic layer, and one of the at least one inorganic layer has a thickness of not larger than 500 nm.

In the embodiment, the encapsulation structure includes a first inorganic structure, an organic layer and a second inorganic structure arranged in sequence along a direction away from the drive substrate, the refractive index of the first inorganic structure is higher than a refractive index of the organic layer, the first inorganic structure includes at least one inorganic layer, and one of the at least one inorganic layer has a thickness of not larger than 500 nm. The above-mentioned design can improve the parallelism of the upper and lower surfaces of the inorganic layer, so as to make the optical fiber effect of the inorganic layer stronger, reduce the exiting probability of the waveguide light, and improve the color deviation phenomenon of the display substrate.

The first inorganic structure may include a plurality of inorganic layers, and one of the inorganic layers has a relatively small thickness of not larger than 500 nm. Alternatively, the first inorganic structure includes only one inorganic layer, and the inorganic layer has a relatively small thickness of not larger than 500 nm.

If the thickness of the inorganic layer in the first inorganic structure is relatively small and not larger than 500 nm, the parallelism of the upper and lower surfaces of the inorganic layer may be improved, making the optical fiber effect of the inorganic layer stronger, reducing the probability of exiting of the waveguide light, and improving the color deviation phenomenon of the display substrate.

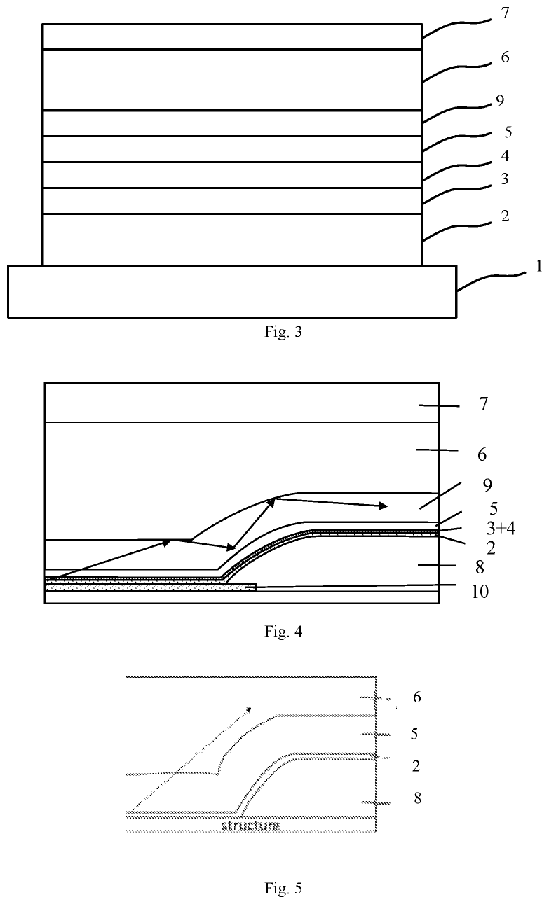

In a particular embodiment, as shown in FIG. 3, the OLED display substrate includes a drive substrate 1, and a light-emitting unit 2, a polaroid 3, a protective layer 4 and an encapsulation structure that are on the drive substrate 1. The drive substrate 1 includes a base substrate and a drive circuit on the base substrate, where the drive circuit includes a thin film transistor array and signal lines, etc. The encapsulation structure includes a first inorganic layer 5, a second inorganic layer 9, an organic layer 6, and a third inorganic layer 7, which are sequentially stacked one by another.

In an embodiment, the first inorganic layer 5, the second inorganic layer 9 and the third inorganic layer 7 have good water-blocking and oxygen-blocking properties, and can ensure packaging reliability.

The first inorganic layer 5 may be made of various materials such as alumina, zinc oxide, silicon oxide, and silicon oxynitride, and preferably silicon oxide. Silicon oxide has a relatively high density and can ensure the reliability of packaging. The first inorganic layer 5 may be prepared using a CVD (chemical vapor deposition) process or an ALD (atomic layer deposition) process, and is preferably prepared using the ALD process, as the first inorganic layer 5 prepared by the ALD process is more compact.

The second inorganic layer 9 may be made of various materials, such as silicon nitride, silicon oxide, silicon oxynitride, aluminium oxide and zinc oxide, and the second inorganic layer 9 may be fabricated through a CVD process or an ALD process, and is preferably made by an ALD process, and the density of the second inorganic layer 9 made by the ALD process is better.

The third inorganic layer 7 may be made of various materials such as alumina, zinc oxide, silicon oxide, and silicon oxynitride, and preferably silicon oxide. Silicon oxide has a relatively high density and can ensure the performance of packaging. The third inorganic layer 7 may be prepared using a CVD process or an ALD process, and is preferably prepared using the ALD process, and the third inorganic layer 7 prepared by the ALD process is more compact.

The organic layer 6 may be prepared by printing a rheological organic material, and the thickness of the organic layer 6 is larger than 6000 nm and may be between 6000 nm and 10000 nm. The refractive index of the second inorganic layer 9 is larger than that of the organic layer 6, and the difference between the refractive indexes may be 0.4 or more.

In the embodiments, the thickness of the first inorganic layer 5 is relatively small and not larger than 100 nm, and may be specifically between 10 nm and 100 nm. In order to ensure the reliability of encapsulation, the first inorganic layer 5 may be prepared by using the ALD process, and the first inorganic layer 5 prepared by the ALD process has a better compactness. However, the refractive index of the first inorganic layer 5 prepared by the ALD process is generally relatively low, being lower than 1.6, and it is also necessary to prepare a second inorganic layer 9, the refractive index of the second inorganic layer 9 is higher than that of the first inorganic layer 5, and is generally not lower than 1.7, so that the second inorganic layer 9 can form an optical fiber-like structure. In addition, the lamination of the second inorganic layer 9 and the first inorganic layer 5 can ensure the reliability of the encapsulation.

The first inorganic layer 5 may have a refractive index ranging from 1.4 to 1.75, and the second inorganic layer 9 has a refractive index higher than the first inorganic layer 5. Since the refractive index of the first inorganic layer 5 is lower than the refractive index of the second inorganic layer 9, as shown in FIG. 4, the light emitted from the light-emitting unit will enter the second inorganic layer 9 via the first inorganic layer 5. Since the refractive index of the second inorganic layer 9 is higher than the refractive index of the organic layer 6, and the difference between the refractive indexes with the organic layer 6 is relatively large, which results in that the light exiting from the light-emitting unit enters the second inorganic layer 9 and propagates by total reflection. The second inorganic layer 9 forms an optical fiber-like structure in the planar structure, as indicated by arrows in FIG. 4, part of the light is trapped in the second inorganic layer 9 to form waveguide light for transverse propagation. In the embodiments, the thickness of the second inorganic layer 9 is not larger than 500 nm, preferably 10 nm to 200 nm. Compared with the thickness of 1 um, the thickness of the second inorganic layer 9 is greatly reduced, so that the parallelism of the upper and lower surfaces of the second inorganic layer 9 is higher, making the optical fiber effect of the second inorganic layer 9 stronger, and reducing the probability of waveguide light exiting; in the region of the pixel definition layer 8, the exiting wave-guiding light can also be reduced, thereby improving the display effect of the OLED display substrate. Reference sign 10 represents an anode of the light-emitting unit of the OLED display substrate.

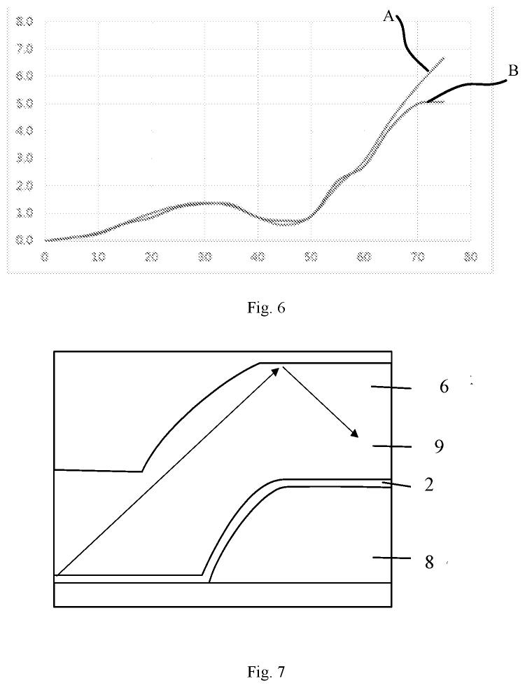

The simulation effect is shown in FIG. 6, where curve A is a large-view-angle white light JNCD curve of the OLED display substrate shown in FIG. 1, curve B is a large-view-angle white light JNCD curve of the OLED display substrate shown in FIG. 3, the abscissa is the degree (deg), the ordinate is the large-view-angle white light JNCD value, and the curve represents JNCD values under different view angles. It can be seen that the large-view-angle white light JNCD decreases significantly after adopting the design as shown in FIG. 3. JNCD is a standard for measuring the accuracy of screen color, where the smaller its value is, the more accurate the color representing screen display is, and the more realistic the effect seen by naked eyes is.

In another particular embodiment, as shown in FIG. 3, an OLED display substrate includes a drive substrate 1, and a light-emitting unit 2, a polaroid 3, a protective layer 4 and an encapsulation structure, which are arranged on the drive substrate 1. The drive substrate 1 includes a base substrate and a drive circuit on the base substrate, where the drive circuit includes a thin film transistor array and signal lines, etc. The encapsulation structure includes a first inorganic layer 5, a second inorganic layer 9, an organic layer 6, and a third inorganic layer 7 which are laminated in sequence.

In this embodiment, the first inorganic layer 5, the second inorganic layer 9 and the third inorganic layer 7 have good water-blocking and oxygen-blocking properties, and can ensure the packaging reliability.

The first inorganic layer 5 may be made of various materials such as alumina, zinc oxide, silicon oxide, and silicon oxynitride, and preferably silicon oxide, where silicon oxide has a relatively high density and can ensure the performance of packaging. The first inorganic layer 5 may be prepared using a CVD process or an ALD process, and is preferably prepared using an ALD process, and the first inorganic layer 5 prepared by the ALD process is more compact.

The second inorganic layer 9 may be made of various materials, such as silicon nitride, silicon oxide, silicon oxynitride, aluminium oxide and zinc oxide, and the second inorganic layer 9 may be made by a CVD process or an ALD process, and is preferably made by an ALD process, and the density of the second inorganic layer 9 made by the ALD process is better.

The third inorganic layer 7 may be made of various materials such as alumina, zinc oxide, silicon oxide, and silicon oxynitride, and preferably silicon oxide, where silicon oxide has a relatively high density and can ensure the performance of packaging. The third inorganic layer 7 may be prepared using a CVD process or an ALD process, and is preferably prepared using the ALD process, and the third inorganic layer 7 prepared by the ALD process is more compact.

The organic layer 6 may be prepared by printing a rheological organic material, and the thickness of the organic layer is larger than 6000 nm and may be between 6000 nm and 100000 nm.

In this embodiment, the thickness of the first inorganic layer 5 is relatively small, and specifically may be between 10 nm and 100 nm, which is not sufficient to ensure the reliability of encapsulation. Therefore, a second inorganic layer 9 is further provided on the first inorganic layer 5, and the lamination of the second inorganic layer 9 and the first inorganic layer 5 can ensure the reliability of encapsulation.

In the embodiments, the difference between the refractive indexes of the second inorganic layer 9 and the organic layer 6 can be reduced by adjusting the material of the second inorganic layer 9 or the material of the organic layer 6 to reduce the refractive index of the second inorganic layer 9 or increase the refractive index of the organic layer 6, so that the difference between the refractive indexes of the second inorganic layer 9 and the organic layer 6 is lower than a preset threshold value, and the preset threshold value may be 0.15, which can improve the total reflection phenomenon of light at the interface between the second inorganic layer 9 and the organic layer 6, and reduce the generation of waveguide light.

As shown in FIG. 5, since the refractive index of the first inorganic layer 5 is not much different from that of the second inorganic layer 9, the light emitted by the light-emitting unit will enter the second inorganic layer 9 via the first inorganic layer 5. After entering the second inorganic layer 9, the light will enter the organic layer 6 via the second inorganic layer 9, since the difference between the refractive indexes of the second inorganic layer 9 and the organic layer 6 is lower than 0.15. Since the difference between the refractive indexes of the organic layer 6 and the third inorganic layer 7 is relatively large (the refractive index of the organic layer 6 is higher than the refractive index of the third inorganic layer 7), the light will propagate horizontally in the film structure formed by the second inorganic layer 9 and the organic layer 6 together. Since the thickness of the organic layer 6 is relatively large, up to about 10 um, the thickness of the film structure formed by the second inorganic layer 9 and the organic layer 6 together is also relatively large, and much larger than the thickness of the pixel definition layer 8 (generally in the range of 2 um to 4 μm). Therefore, in the region of the pixel definition layer 8, the film structure formed by the combination of the second inorganic layer 9 and the organic layer 6 is also approximately flat, and can reduce the exiting waveguide light, thereby improving the display effect of the OLED display substrate.

In order to improve the flatness of the film structure composed of the second inorganic layer 9 and the organic layer 6 together, the thickness of the second inorganic layer 9 may be set to be relatively large, larger than 1500 nm, for example 50000 nm. Of course, since the thickness of the organic layer 6 is relatively large, the flatness of the film structure composed of the second inorganic layer 9 and the organic layer 6 can already be ensured, and the second inorganic layer 9 may also be set relatively small, for example 10 nm. Therefore, the thickness of the second organic layer 9 may be 10 nm to 50000 nm.

In yet another particular embodiment, as shown in FIG. 3, an OLED display substrate includes a drive substrate 1, and a light-emitting unit 2, a polaroid 3, a protective layer 4 and an encapsulation structure, which are located on the drive substrate 1. The drive substrate 1 includes a base substrate and a drive circuit on the base substrate, where the drive circuit includes a thin film transistor array and signal lines, etc. The encapsulation structure includes a first inorganic layer 5, a second inorganic layer 9, an organic layer 6, and a third inorganic layer 7 which are laminated in sequence.

In the embodiments, the first inorganic layer 5, the second inorganic layer 9 and the third inorganic layer 7 have good water-blocking and oxygen-blocking properties, and can ensure the reliability of encapsulation.

The first inorganic layer 5 may be made of various materials such as alumina, zinc oxide, silicon oxide, and silicon oxynitride, and preferably silicon oxide, where silicon oxide has a relatively high density and can ensure the performance of packaging. The first inorganic layer 5 may be prepared using a CVD process or an ALD process, and is preferably prepared using an ALD process, and the first inorganic layer 5 prepared by the ALD process is more compact.

The second inorganic layer 9 may be made of various materials, such as silicon nitride, silicon oxide, silicon oxynitride, aluminium oxide and zinc oxide, and the second inorganic layer 9 may be made by a CVD process or an ALD process, and is preferably made by an ALD process, and the density of the second inorganic layer 9 made by the ALD process is better.

The third inorganic layer 7 may be made of various materials such as alumina, zinc oxide, silicon oxide, and silicon oxynitride, and preferably silicon oxide, where silicon oxide has a relatively high density and can ensure the performance of packaging. The third inorganic layer 7 may be prepared using a CVD process or an ALD process, and is preferably prepared using the ALD process, and the third inorganic layer 7 prepared by the ALD process is more compact.

The organic layer 6 may be prepared by printing a rheological organic material, the thickness of the organic layer being larger than 6000 nm and may be between 6000 nm and 1000 nm. The refractive index of the second inorganic layer 9 is larger than that of the organic layer 6, and the difference between the refractive indexes may be 0.4 or more.

The thickness of the first inorganic layer 5 is relatively small, smaller than 500 nm, and may be specifically between 10 nm to 100 nm, which is not sufficient to ensure the encapsulation reliability. Therefore, a second inorganic layer 9 is further provided on the first inorganic layer 5, and the lamination of the second inorganic layer 9 and the first inorganic layer 5 can ensure the reliability of encapsulation. The thickness of the second inorganic layer 9 may be set relatively large, larger than 1.5 um.

As shown in FIG. 5, since the difference between the refractive index of the first inorganic layer 5 and the refractive index of the second inorganic layer 9 is small, the light exiting the light-emitting unit will pass through the first inorganic layer 5 and enter the second inorganic layer 9. Since the difference between the refractive index of the organic layer 6 and the second inorganic layer 9 is relatively large, the light will propagate laterally in the second inorganic layer 9. Since the thickness of the second inorganic layer 9 is relatively large, up to about 1.5 um, the proportion of the waveguide light reflected at the pixel definition layer will be reduced. As shown in FIG. 7, most of the light will propagate directly above the pixel definition layer 8 as shown by the arrows in the figure rather than being reflected by the slope of the pixel definition layer 8, which is similar to planar propagation. Thus, the exiting waveguide light can be reduced, thereby improving the display effect of the OLED display substrate.

In still another particular embodiment, as shown in FIG. 1, an OLED display substrate includes a drive substrate 1, and a light-emitting unit 2, a polaroid 3, a protective layer 4 and an encapsulation structure, which are arranged on the drive substrate 1. The drive substrate 1 includes a base substrate and a drive circuit on the base substrate, where the drive circuit includes a thin film transistor array and signal lines, etc. The encapsulation structure includes a first inorganic layer 5, an organic layer 6, and a third inorganic layer 7, which are laminated in sequence.

In this embodiment, the thickness of the first inorganic layer 5 is relatively small, smaller than 500 nm, preferably lower than 100 nm, and in order to ensure the reliability of the encapsulation, the first inorganic layer 5 may be prepared by using the ALD process, and the density of the first inorganic layer 5 prepared by the ALD process is better.

The first inorganic layer 5 may be made of various materials such as alumina, zinc oxide, silicon oxide, and silicon oxynitride, and preferably silicon oxide, where silicon oxide has a relatively high density and can ensure the performance of packaging.

The third inorganic layer 7 may be made of various materials such as alumina, zinc oxide, silicon oxide, and silicon oxynitride, and preferably silicon oxide, where silicon oxide has a relatively high density and can ensure the performance of packaging. The third inorganic layer 7 may be prepared using a CVD process or an ALD process, and is preferably prepared using the ALD process, and the third inorganic layer 7 prepared by the ALD process is more compact.

The organic layer 6 may be prepared by printing a rheological organic material, the thickness of the organic layer being larger than 6000 nm and may be between 6000 nm and 1000 nm. The refractive index of the first inorganic layer 5 is larger than that of the organic layer 6, and the difference in the refractive indexes may be 0.4 or more.

Since the refractive index of the first inorganic layer 5 is much higher than the refractive index of the organic layer 6, the difference in the refractive indexes at the interface between the first inorganic layer 5 and the organic layer 6 is relatively large, which results in that after the light emitted by the light-emitting unit is incident on the first inorganic layer 5, the first inorganic layer 5 forms an optical fiber-like structure in the planar structure, and part of the light is trapped into the first inorganic layer 5 to form waveguide light for transverse propagation. Since the thickness of the first inorganic layer 5 is small, in the region of the pixel definition layer 8, the parallelism of the upper and lower surfaces of the first inorganic layer 5 is higher, so that the optical fiber effect of the first inorganic layer 5 is stronger, and the probability of exiting of the waveguide light is reduced; in the region of the pixel definition layer 8, the exiting waveguide light can also be reduced, thereby improving the display effect of the OLED display substrate.

An embodiment of the present disclosure further provides a display device including the OLED display substrate described above.

The display device includes, but not limited to: a radio frequency unit, a network module, an audio output unit, an input unit, a sensor, a display unit, a user input unit, an interface unit, a memory, a processor, a power supply, etc. It will be appreciated by those skilled in the art that the configuration of the display device described above is not intended to be limiting and that the display device may include more or fewer of the components described above, or some combinations of the components, or different arrangements of the components. In embodiments of the present disclosure, the display device includes, but not limited to, a display, a cell phone, a tablet, a television, a wearable electronic device, a navigation display device, etc.

The display device may be: any product or component with a display function, such as a television, a display, a digital photo frame, a mobile phone, a tablet computer, and among others, the display device further includes a flexible circuit board, a printed circuit board and a back plate.

An embodiment of the present disclosure further provides a method for manufacturing an OLED display substrate, including:
providing a drive substrate;
forming a light-emitting unit on the drive substrate; and
forming an encapsulation structure covering the light-emitting unit.

The forming the encapsulation structure includes: forming a first inorganic structure, an organic layer and a second inorganic structure in sequence. A refractive index of the first inorganic structure higher than a refractive index of the organic layer, the first inorganic structure includes at least one inorganic layer, and one of the at least one inorganic layer has a thickness of not larger than 500 nm.

In this embodiment, the encapsulation structure includes a first inorganic structure, an organic layer and a second inorganic structure arranged in sequence along a direction away from the drive substrate, a refractive index of the first inorganic structure is higher than a refractive index of the organic layer, the first inorganic structure includes at least one inorganic layer, and one of the at least one inorganic layer has a thickness of not larger than 500 nm. With the above design, it can be avoided that the light propagating laterally in the first inorganic structure is mixed into normal emergent light of the display substrate, improving the color deviation of the display substrate.

The first inorganic structure may include a plurality of inorganic layers, and one of the inorganic layers has a relatively small thickness of not larger than 500 nm. Alternatively, the first inorganic structure includes only one inorganic layer, and the inorganic layer has a relatively small thickness of not larger than 500 nm.

If the thickness of the inorganic layer in the first inorganic structure is small and not larger than 500 nm, the parallelism of the upper and lower surfaces of the inorganic layer is improved, enhancing the optical fiber effect of the inorganic layer, reducing the exiting probability of waveguide light, and improving the color deviation phenomenon of the display substrate.

In some embodiments, the step of forming the first inorganic structure includes: forming a first inorganic layer and a second inorganic layer that are laminated, where a refractive index of the first inorganic layer is lower than a refractive index of the second inorganic layer, and the first inorganic layer has a thickness of not larger than 500 nm.

In a particular embodiment, as shown in FIG. 3, an OLED display substrate includes a drive substrate 1, and a light-emitting unit 2, a polaroid 3, a protective layer 4 and an encapsulation structure, which are located on the drive substrate 1. The drive substrate 1 includes a base substrate and a drive circuit on the base substrate, where the drive circuit includes a thin film transistor array and signal lines, etc. The step of forming the encapsulation structure includes: sequentially forming a first inorganic layer 5, a second inorganic layer 9, an organic layer 6 and a third inorganic layer 7.

In this embodiment, the first inorganic layer 5, the second inorganic layer 9 and the third inorganic layer 7 have good water-blocking and oxygen-blocking properties, and can ensure packaging reliability.

The first inorganic layer 5 may be made of various materials such as alumina, zinc oxide, silicon oxide, and silicon oxynitride, and preferably silicon oxide, where silicon oxide has a relatively high density and can ensure the reliability of encapsulation. The first inorganic layer 5 may be prepared using a CVD (chemical vapour deposition) process or an ALD (atomic layer deposition) process, and is preferably prepared using an ALD process, and the first inorganic layer 5 prepared by the ALD process is more compact.

The second inorganic layer 9 may be made of various materials, such as silicon nitride, silicon oxide, silicon oxynitride, aluminium oxide and zinc oxide, and the second inorganic layer 9 may be made by a CVD process or an ALD process, and is preferably made by an ALD process, and the density of the second inorganic layer 9 made by the ALD process is better.

The third inorganic layer 7 may be made of various materials such as alumina, zinc oxide, silicon oxide, and silicon oxynitride, and preferably silicon oxide, where silicon oxide has a relatively high density and can ensure the performance of packaging. The third inorganic layer 7 may be prepared using a CVD process or an ALD process, and is preferably prepared using the ALD process, and the third inorganic layer 7 prepared by the ALD process is more compact.

The organic layer 6 may be prepared by printing a rheological organic material, and the thickness of the organic layer 6 is larger than 6000 nm and may be between 6000 nm and 10000 nm. The refractive index of the second inorganic layer 9 is larger than that of the organic layer 6, and the difference between the refractive indexes may be 0.4 or more.

In this embodiment, the thickness of the first inorganic layer 5 is relatively small and not larger than 100 nm, and may be specifically between 10 nm and 100 nm. In order to ensure the reliability of encapsulation, the first inorganic layer 5 may be prepared by using the ALD process, and the density of the first inorganic layer 5 prepared by the ALD process is better. However, the refractive index of the first inorganic layer 5 prepared by the ALD process is generally relatively low, being lower than 1.6, and it is also necessary to prepare a second inorganic layer 9, the refractive index of the second inorganic layer 9 is higher than that of the first inorganic layer 5, and is generally not lower than 1.7, so that the second inorganic layer 9 can form an optical fiber-like structure. In addition, the lamination of the second inorganic layer 9 and the first inorganic layer 5 can ensure the reliability of the encapsulation.

The first inorganic layer 5 may have a refractive index of 1.4 to 1.75, and the second inorganic layer 9 has a refractive index higher than the first inorganic layer 5. Since the refractive index of the first inorganic layer 5 is low than the refractive index of the second inorganic layer 9, as shown in FIG. 4, the light emitted from the light-emitting unit will enter the second inorganic layer 9 via the first inorganic layer 5. Since the refractive index of the second inorganic layer 9 is higher than the refractive index of the organic layer 6, and the difference between the refractive indexes with the organic layer 6 is relatively large, which results in that the light exiting the light-emitting unit enters the second inorganic layer 9 and propagates by total reflection, and the second inorganic layer 9 forms an optical fiber-like structure in the planar structure, as shown by arrows in FIG. 4, part of the light is limited to the second inorganic layer 9 to form waveguide light for transverse propagation. In this embodiment, the thickness of the second inorganic layer 9 is not larger than 500 nm, preferably 10 nm to 200 nm. Compared with the thickness of 1 um, the thickness of the second inorganic layer 9 is greatly reduced, so that the parallelism of the upper and lower surfaces of the second inorganic layer 9 is higher, making the optical fiber effect of the second inorganic layer 9 stronger, and reducing the probability of waveguide light exiting; in the region of the pixel definition layer 8, the exiting waveguide light can also be reduced, thereby improving the display effect of the OLED display substrate. Reference sign 10 represents an anode of the light-emitting unit of the OLED display substrate.

The simulation effect is shown in FIG. 6, where curve A is a large-view-angle white light JNCD curve of the OLED display substrate shown in FIG. 1, curve B is a large-view-angle white light JNCD curve of the OLED display substrate shown in FIG. 3, the abscissa is the degree (deg), the ordinate is the large-view-angle white light JNCD value, and the curve represents JNCD values under different view angles. It can be seen that the large-view-angle white light JNCD decreases significantly after adopting the design as shown in FIG. 3. JNCD is a standard for measuring the accuracy of screen color, where the smaller its value is, the more accurate the color representing screen display is, and the more realistic the effect seen by naked eyes is.

In another particular embodiment, as shown in FIG. 3, an OLED display substrate includes a drive substrate 1, and a light-emitting unit 2, a polaroid 3, a protective layer 4 and an encapsulation structure, which are arranged on the drive substrate 1. The drive substrate 1 includes a base substrate and a drive circuit on the base substrate, where the drive circuit includes a thin film transistor array and signal lines, etc. The step of forming the encapsulation structure includes: forming a first inorganic layer 5, a second inorganic layer 9, an organic layer 6, and a third inorganic layer 7, which are laminated in sequence.

In this embodiment, the first inorganic layer 5, the second inorganic layer 9 and the third inorganic layer 7 have good water-blocking and oxygen-blocking properties, and can ensure packaging reliability.

The first inorganic layer 5 may be made of various materials such as alumina, zinc oxide, silicon oxide, and silicon oxynitride, and preferably silicon oxide, where silicon oxide has a relatively high density and can ensure the performance of packaging. The first inorganic layer 5 may be prepared using a CVD process or an ALD process, and is preferably prepared using an ALD process, and the first inorganic layer 5 prepared by the ALD process is more compact.

The second inorganic layer 9 may be made of various materials, such as silicon nitride, silicon oxide, silicon oxynitride, aluminium oxide and zinc oxide, and the second inorganic layer 9 may be made by a CVD process or an ALD process, and is preferably made by an ALD process, and the density of the second inorganic layer 9 made by the ALD process is better.

The third inorganic layer 7 may be made of various materials such as alumina, zinc oxide, silicon oxide, and silicon oxynitride, and preferably silicon oxide, where silicon oxide has a relatively high density and can ensure the performance of packaging. The third inorganic layer 7 may be prepared using a CVD process or an ALD process, and is preferably prepared using the ALD process, and the third inorganic layer 7 prepared by the ALD process is more compact.

The organic layer 6 may be prepared by printing a rheological organic material, and the thickness of the organic layer is larger than 6000 nm and may be between 6000 nm and 100000 nm.

In the embodiments, the thickness of the first inorganic layer 5 is relatively small, and specifically may be between 10 nm and 100 nm, which is not sufficient to ensure the reliability of encapsulation. Therefore, a second inorganic layer 9 is further provided on the first inorganic layer 5, and the lamination of the second inorganic layer 9 and the first inorganic layer 5 can ensure the reliability of encapsulation.

In this embodiment, the difference between the refractive indexes of the second inorganic layer 9 and the organic layer 6 can be reduced by adjusting the material of the second inorganic layer 9 or the material of the organic layer 6 to reduce the refractive index of the second inorganic layer 9 or increase the refractive index of the organic layer 6, so that the difference between the refractive indexes of the second inorganic layer 9 and the organic layer 6 is lower than a preset threshold value, and the preset threshold value may be 0.15, which can improve the total reflection phenomenon of light at the interface between the second inorganic layer 9 and the organic layer 6, and reduce the generation of waveguide light.

As shown in FIG. 5, since the refractive index of the first inorganic layer 5 is not much different from that of the second inorganic layer 9, the light emitted by the light-emitting unit will enter the second inorganic layer 9 via the first inorganic layer 5. After entering the second inorganic layer 9, the light will enter the organic layer 6 via the second inorganic layer 9, since the difference between the refractive indexes of the second inorganic layer 9 and the organic layer 6 is lower than 0.15. Since the difference between the refractive indexes of the organic layer 6 and the third inorganic layer 7 is relatively large (the refractive index of the organic layer 6 is higher than the refractive index of the third inorganic layer 7), the light will propagate horizontally in the film structure formed by the second inorganic layer 9 and the organic layer 6 together. Since the thickness of the organic layer 6 is relatively large, up to about 10 um, the thickness of the film structure formed by the second inorganic layer 9 and the organic layer 6 together is also relatively large, and much larger than the thickness of the pixel definition layer 8 (generally in the range of 2 um to 4 μm). Therefore, in the region of the pixel definition layer 8, the film structure formed by the combination of the second inorganic layer 9 and the organic layer 6 is also approximately flat, and can reduce the exiting waveguide light, thereby improving the display effect of the OLED display substrate.

In order to improve the flatness of the film structure composed of the second inorganic layer 9 and the organic layer 6 together, the thickness of the second inorganic layer 9 may be set to be relatively large, larger than 1500 nm, for example 50000 nm. Of course, since the thickness of the organic layer 6 is relatively large, the flatness of the film structure composed of the second inorganic layer 9 and the organic layer 6 can already be ensured, and the second inorganic layer 9 may also be set relatively small, for example 10 nm. Therefore, the thickness of the second organic layer 9 may be 10 nm to 50000 nm.

In yet another particular embodiment, as shown in FIG. 3, an OLED display substrate includes a drive substrate 1, a light-emitting unit 2 on the drive substrate 1, a polaroid 3, a protective layer 4, and an encapsulation structure. The drive substrate 1 includes a base substrate and a drive circuit on the base substrate, where the drive circuit includes a thin film transistor array and signal lines, etc. The step of forming the encapsulation structure includes: forming a first inorganic layer 5, a second inorganic layer 9, an organic layer 6, and a third inorganic layer 7 which are laminated in sequence.

In this embodiment, the first inorganic layer 5, the second inorganic layer 9 and the third inorganic layer 7 have good water-blocking and oxygen-blocking properties, and can ensure packaging reliability.

The first inorganic layer 5 may be made of various materials such as alumina, zinc oxide, silicon oxide, and silicon oxynitride, and preferably silicon oxide, where silicon oxide has a relatively high density and can ensure the performance of packaging. The first inorganic layer 5 may be prepared using a CVD process or an ALD process, and is preferably prepared using an ALD process, and the first inorganic layer 5 prepared by the ALD process is more compact.

The second inorganic layer 9 may be made of various materials, such as silicon nitride, silicon oxide, silicon oxynitride, aluminium oxide and zinc oxide, and the second inorganic layer 9 may be made by a CVD process or an ALD process, and is preferably made by an ALD process, and the density of the second inorganic layer 9 made by the ALD process is better.

The third inorganic layer 7 may be made of various materials such as alumina, zinc oxide, silicon oxide, and silicon oxynitride, and preferably silicon oxide, where silicon oxide has a relatively high density and can ensure the performance of packaging. The third inorganic layer 7 may be prepared using a CVD process or an ALD process, and is preferably prepared using the ALD process, and the third inorganic layer 7 prepared by the ALD process is more compact.

The organic layer 6 may be prepared by printing a rheological organic material, the thickness of the organic layer being larger than 6000 nm and may be between 6000 nm and 1000 nm. The refractive index of the second inorganic layer 9 is larger than that of the organic layer 6, and the difference between the refractive indexes may be 0.4 or more.

The thickness of the first inorganic layer 5 is relatively small, smaller than 500 nm, and may be specifically between 10 nm to 100 nm, which is not sufficient to ensure the encapsulation reliability. Therefore, a second inorganic layer 9 is further provided on the first inorganic layer 5, and the lamination of the second inorganic layer 9 and the first inorganic layer 5 can ensure the reliability of encapsulation. The thickness of the second inorganic layer 9 may be set relatively large, greater than 1.5 um.

As shown in FIG. 5, since the difference between the refractive index of the first inorganic layer 5 and the refractive index of the second inorganic layer 9 is small, the light exiting the light-emitting unit will pass through the first inorganic layer 5 and enter the second inorganic layer 9. Since the difference between the refractive index of the organic layer 6 and the second inorganic layer 9 is relatively large, the light will propagate laterally in the second inorganic layer 9. Since the thickness of the second inorganic layer 9 is relatively large, up to about 1.5 um, the proportion of the waveguide light reflected at the pixel definition layer will be reduced. As shown in FIG. 7, most of the light will propagate directly above the pixel definition layer 8 as shown by the arrows in the figure rather than being reflected by the slope of the pixel definition layer 8, similar to planar propagation, the exiting waveguide light can be reduced, thereby improving the display effect of the OLED display substrate.

In some embodiments, the step of forming the first inorganic structure includes: forming a first inorganic layer having a thickness of smaller than 500 nm.

As shown in FIG. 1, an OLED display substrate includes a drive substrate 1, and a light-emitting unit 2, a polaroid 3, a protective layer 4, and an encapsulation structure, which are arranged on the drive substrate 1. The drive substrate 1 includes a base substrate and a drive circuit on the base substrate, where the drive circuit includes a thin film transistor array and signal lines, etc. The step of forming the encapsulation structure includes: forming a first inorganic layer 5, an organic layer 6, and a third inorganic layer 7 that are laminated in sequence.

In this embodiment, the thickness of the first inorganic layer 5 is relatively small, smaller than 500 nm, preferably smaller than 100 nm, and in order to ensure the reliability of the encapsulation, the first inorganic layer 5 may be prepared by using the ALD process, and the density of the first inorganic layer 5 prepared by the ALD process is better.

The first inorganic layer 5 may be made of various materials such as alumina, zinc oxide, silicon oxide, and silicon oxynitride, and preferably silicon oxide, where silicon oxide has a relatively high density and can ensure the performance of packaging.

The third inorganic layer 7 may be made of various materials such as alumina, zinc oxide, silicon oxide, and silicon oxynitride, and preferably silicon oxide, where silicon oxide has a relatively high density and can ensure the performance of packaging. The third inorganic layer 7 may be prepared using a CVD process or an ALD process, and is preferably prepared using the ALD process, and the third inorganic layer 7 prepared by the ALD process is more compact.

The organic layer 6 may be prepared by printing a rheological organic material, the thickness of the organic layer being larger than 6000 nm and may be between 6000 nm and 1000 nm. The refractive index of the first inorganic layer 5 is larger than that of the organic layer 6, and the difference in the refractive indexes may be 0.4 or more.

Since the refractive index of the first inorganic layer 5 is much higher than the refractive index of the organic layer 6, the difference in the refractive indexes at the interface between the first inorganic layer 5 and the organic layer 6 is relatively large, which results in that after the light emitted by the light-emitting unit is incident on the first inorganic layer 5, the first inorganic layer 5 forms an optical fiber-like structure in the planar structure, and part of the light is limited to the first inorganic layer 5 to form waveguide light for transverse propagation. Since the thickness of the first inorganic layer 5 is small, in the region of the pixel definition layer 8, the parallelism of the upper and lower surfaces of the first inorganic layer 5 is higher, so that the optical fiber effect of the first inorganic layer 5 is stronger, and the probability of waveguide light exiting is reduced; in the region of the pixel definition layer 8, the exiting waveguide light can also be reduced, thereby improving the display effect of the OLED display substrate.

It should be noted that various embodiments described herein are described in a progressive manner with reference to the same or similar parts throughout the various embodiments, with each embodiment focusing on differences from the other embodiments. In particular, the embodiments are described more simply because they are substantially similar to the product embodiments, with reference to the partial description of the product embodiments.

Unless defined otherwise, technical or scientific terms used in this disclosure shall have the ordinary meaning as understood by one of ordinary skill in the art to which this disclosure belongs. Such terms as “first” and “second” as used herein do not denote any order, quantity, or importance, but rather are used to distinguish one element from another. Such terms as “comprise” and “include” means that the presence of an element or item preceding the word covers the presence of the element or item listed after the word and equivalents thereof, but does not exclude other elements or items. Such terms as “connecting” and “connected” are not limited to physical or mechanical connections, but may include electrical connections, whether direct or indirect. Such terms as “upper”, “lower”, “left” and “right” are used only to indicate relative positional relationships that may change accordingly when the absolute position of the object being described changes.

It will be understood that when an element such as a layer, film, region or substrate is referred to as being “on” or “under” another element, it can be “directly on” or “directly under” the other element or intervening elements may be present.

In the description of the embodiments above, particular features, structures, materials, or characteristics may be combined in any suitable manner in any one or more embodiments or examples.

The above implementations are only specific embodiments of the present disclosure, but the protection scope of the present disclosure is not limited herein. A person of ordinary skill in the art can think of changes or substitutions within the technical scope of the present disclosure, which shall fall within the protection scope of the present disclosure. Therefore, the protection scope of the present disclosure is as set forth in the claims below.

1. An OLED display substrate, comprising:
a drive substrate, the drive substrate being provided with a light-emitting unit; and
an encapsulation structure covering the light-emitting unit;
wherein the encapsulation structure comprises a first inorganic structure, an organic layer and a second inorganic structure that are arranged in sequence along a direction away from the drive substrate;
a refractive index of the first inorganic structure is higher than a refractive index of the organic layer, the first inorganic structure comprises at least one inorganic layer, and a thickness of one inorganic layer of the at least one inorganic layer is not larger than 500 nm.

2. The OLED display substrate according to claim 1, wherein along the direction away from the drive substrate, the first inorganic structure comprises a first inorganic layer and a second inorganic layer that are laminated, a refractive index of the first inorganic layer is lower than a refractive index of the second inorganic layer, and a thickness of the first inorganic layer is not larger than 500 nm.

3. The OLED display substrate according to claim 2, wherein the thickness of the first inorganic layer is not larger than 100 nm, and a thickness of the second inorganic layer is not larger than 500 nm.

4. The OLED display substrate according to claim 2, wherein a difference between the refractive index of the second inorganic layer and the refractive index of the organic layer is smaller than a preset threshold.

5. The OLED display substrate according to claim 4, wherein the preset threshold is 0.15.

6. The OLED display substrate according to claim 4, wherein a thickness of the organic layer is larger than 6000 nm.

7. The OLED display substrate according to claim 4, wherein a thickness of the second organic layer is 10 nm to 50000 nm.

8. The OLED display substrate according to claim 2, wherein a thickness of the second organic layer is larger than 1500 nm.

9. The OLED display substrate according to claim 1, wherein the first inorganic structure comprises only one first inorganic layer, and a thickness of the first inorganic layer is smaller than 500 nm.

10. A display device, comprising the OLED display substrate according to claim 1.

11. A method for manufacturing an OLED display substrate, comprising:
providing a drive substrate;
forming a light-emitting unit on the drive substrate; and
forming an encapsulation structure covering the light-emitting unit;
wherein the forming the encapsulation structure comprises:
forming a first inorganic structure, an organic layer and a second inorganic structure in sequence, wherein a refractive index of the first inorganic structure is higher than a refractive index of the organic layer, the first inorganic structure comprises at least one inorganic layer, and a thickness of one inorganic layer of the at least one inorganic layer is not larger than 500 nm.

12. The method for manufacturing an OLED display substrate according to claim 11, wherein the forming the first inorganic structure comprises:
forming a first inorganic layer and a second inorganic layer that are laminated, a refractive index of the first inorganic layer is lower than a refractive index of the second inorganic layer, and a thickness of the first inorganic layer is not larger than 500 nm.

13. The method for manufacturing an OLED display substrate according to claim 11, wherein the forming the first inorganic structure comprises:
forming a first inorganic layer, a thickness of the first inorganic layer being not larger than 500 nm.

14. The method for manufacturing an OLED display substrate according to claim 12, wherein the forming the first inorganic layer comprises:
forming the first inorganic layer in an atomic layer deposition (ALD) manner.
